(19) United States
(12) Patent Application Publication
(10) Pub. No.: US 2008/0199332 A1
(43) Pub. Date: Aug. 21, 2008

(54) PIEZOELECTRIC PUMP AND PIEZOELECTRIC VIBRATOR

(75) Inventors: Akira SATOH, Niigata-ken (JP); Hitoshi Onishi, Niigata-ken (JP); Jiro Nakajima, Niigata-ken (JP); Eiichi Komai, Niigata-ken (JP)

Correspondence Address: HUNTON & WILLIAMS LLP;INTELLECTUAL PROPERTY DEPARTMENT, 1900 K STREET, N.W., SUITE 1200, WASHINGTON, DC, 20006-1109, US

(73) Assignee: ALPS ELECTRIC CO., LTD, Tokyo (JP)

(21) Appl. No.: 12/032,354

(22) Filed: Feb. 15, 2008

(30) Foreign Application Priority Data
Feb. 16, 2007 (JP) 2007-035879

(51) Int. Cl. F04B 17/03; H01L 41/08

(52) U.S. Cl. 417/413.2; 310/324

(57) ABSTRACT

Embodiments of the present disclosure may include a piezoelectric pump having: a piezoelectric vibrator whose periphery may be fluid-tightly sealed; and a pump chamber and an air chamber that may be formed on front and rear sides of the piezoelectric vibrator. The piezoelectric vibrator may include: a main shim that may be formed of a conductive thin metal plate; a plurality of piezoelectric element layers that may be formed on the main shim; and an intermediate shim that may be formed between the plurality of piezoelectric element layers and may be made of an elastic metal material having mechanical recovery. The piezoelectric vibrator may be vibrated to perform a pumping operation.

### CROSS-REFERENCE TO RELATED APPLICATIONS

This application claims benefit of the Japanese Patent Application No. 2007-035879 filed on Feb. 16, 2007, the entire content of which is hereby incorporated by reference.

### BACKGROUND

1. Field of the Disclosure

The present disclosure relates to a piezoelectric vibrator and a piezoelectric pump that performs a pumping operation using the vibration of the piezoelectric vibrator.

2. Description of the Related Art

In general, a piezoelectric pump includes a piezoelectric vibrator whose periphery is fluid-tightly sealed, a pump chamber and an air chamber that are provided on the front and rear sides of the piezoelectric vibrator, and a pair of check valves (including a check value that allows the flow of liquid to the pump chamber and a check valve that allows the flow of liquid from the pump chamber) that are provided on a pair of flow passages communicating with the pump chamber and allow liquid to flow in opposite directions. When the piezoelectric vibrator is vibrated, the volume of the pump chamber varies, which causes one of the pair of check valves to be opened and the other check value to be closed. This operation is repeated to perform a pumping operation. Such a piezoelectric pump has been used as, for example, a coolant circulating pump for a water-cooled notebook computer. This type of piezoelectric vibrator is disclosed in, for example, JP-A-8-288564, JP-A-11-27963, and JP-A-6-117377.

The piezoelectric pump requires high closing pressure (the internal pressure of a discharge passage (system) when suction and discharge umbrellas (check valves) are closed (when no liquid flows)) rather than a large amplitude of the piezoelectric vibrator. In the piezoelectric vibrator according to the related art, it is possible to increase the amplitude of vibration by reducing the thickness of the shim. However, in this case, the mechanical strength of the shim is weakened, which makes it difficult to increase the closing pressure of the piezoelectric vibrator.

### SUMMARY

Embodiments of the present disclosure may provide a piezoelectric vibrator and a piezoelectric pump capable of improving the mechanical strength and support strength of the piezoelectric vibrator and increasing the closing pressure thereof while reducing the thickness of a shim.

According to an embodiment of the present disclosure, a piezoelectric pump may include: a piezoelectric vibrator whose periphery is fluid-tightly sealed; and a pump chamber and an air chamber that are formed on front and rear sides of the piezoelectric vibrator. The piezoelectric vibrator includes: a main shim that is formed of a conductive thin metal plate; a plurality of piezoelectric element layers that are formed on the main shim; and an intermediate shim that is formed between the plurality of piezoelectric element layers and is made of an elastic metal material having mechanical recovery. The piezoelectric vibrator may be vibrated to perform a pumping operation.

In the piezoelectric pump according to an embodiment of the present disclosure, the intermediate shim may be provided in the middle of the plurality of piezoelectric element layers.

In the piezoelectric pump according to this embodiment, in the piezoelectric vibrator, one surface of the main shim may abut on the pumping chamber, and the plurality of piezoelectric element layers and the intermediate shim may be formed on the other surface of the main shim. The plurality of piezoelectric element layers and the intermediate shim may be formed on both surfaces of the main shim.

In the piezoelectric pump according to an embodiment of the present disclosure, the intermediate shim may have higher mechanical recovery than the main shim. Specifically, the intermediate shim and the main shim may be formed of the same material, and the thickness of the intermediate shim may be larger than that of the main shim.

In the piezoelectric pump according to an embodiment of the present disclosure, the plurality of piezoelectric element layers may be polarized and connected to wiring lines such that the amplitude of the vibration of the piezoelectric vibrator is larger than that of a piezoelectric vibrator including a single-layer piezoelectric element.

In the piezoelectric pump according to an embodiment of the present disclosure, the intermediate shim of the piezoelectric vibrator may have a smaller diameter than a piezoelectric element layer below the intermediate shim, and a pair of ring-shaped support members may support both sides of a circumferential portion of the piezoelectric element layer below the intermediate shim.

In the piezoelectric pump according to an embodiment of the present disclosure, the intermediate shim of the piezoelectric vibrator may have a larger diameter than a piezoelectric element layer above the intermediate shim, and a pair of ring-shaped support members may support both sides of a circumferential portion of a laminate of the intermediate shim, the main shim, and a piezoelectric element layer interposed between the two shims.

According to another embodiment of the present disclosure, a piezoelectric vibrator may include: a main shim that is formed of an elastic metal material having mechanical recovery; a plurality of piezoelectric element layers that are formed on the main shim; and an intermediate shim that is formed of an elastic metal material having mechanical recovery and is provided between the plurality of piezoelectric element layers.

In the piezoelectric vibrator according to an embodiment of the present disclosure, the intermediate shim may have higher mechanical recovery than the main shim. Specifically, the intermediate shim and the main shim may be formed of the same material, and the thickness of the intermediate shim may be larger than that of the main shim.

### BRIEF DESCRIPTION OF THE DRAWINGS

FIG. 1 depicts an expanded perspective view illustrating the basic structure of a piezoelectric pump according to an embodiment of the present disclosure;

FIG. 2 depicts a cross-sectional view illustrating the piezoelectric pump, according to an embodiment of the present disclosure;

FIG. 3 depicts a partial enlarged cross-sectional view illustrating a piezoelectric vibrator according to an embodiment of the present disclosure;

FIG. 4 depicts a cross-sectional view schematically illustrating the piezoelectric vibrator, according to an embodiment of the present disclosure;

FIG. 5 depicts a cross-sectional view schematically illustrating a piezoelectric vibrator according to another embodiment of the present disclosure;

FIG. 6 depicts a cross-sectional view schematically illustrating a piezoelectric vibrator according to another embodiment of the present disclosure;

FIG. 7 depicts a cross-sectional view illustrating schematically illustrating a piezoelectric vibrator according to another embodiment of the present disclosure; and

FIG. 8 depicts a graph illustrating the flow rate and the pressure of liquid measured at a predetermined position in a flow passage while varying the thickness of an intermediate shim, according to an embodiment of the present disclosure.

### DESCRIPTION OF THE EMBODIMENTS

According to the disclosure, the closing pressure of a piezoelectric vibrator may be increased while preventing a reduction in the amplitude of vibration by forming a plurality of piezoelectric layers on a shim of the piezoelectric vibrator and forming an intermediate shim between the piezoelectric element layers.

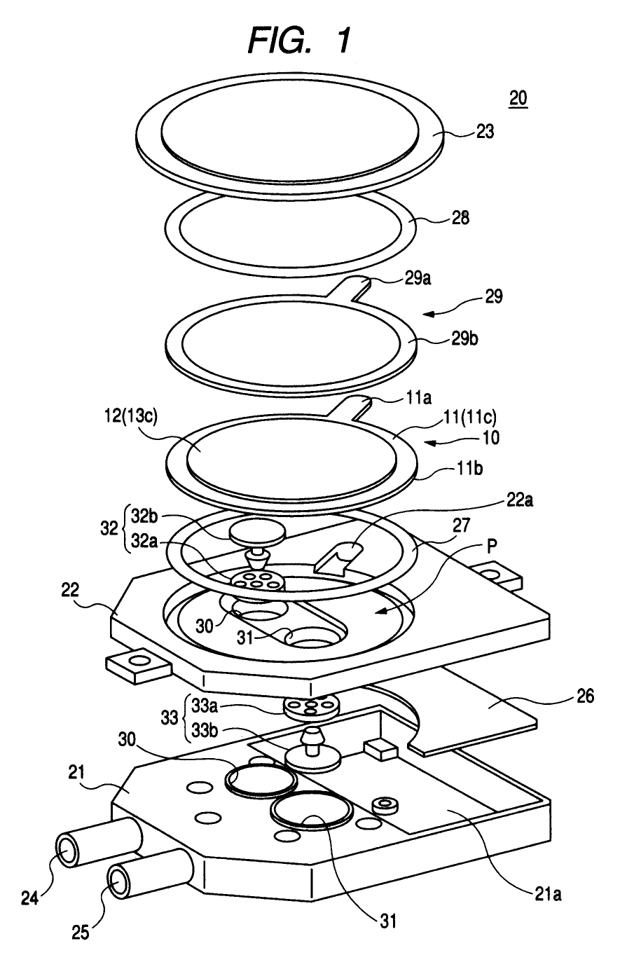

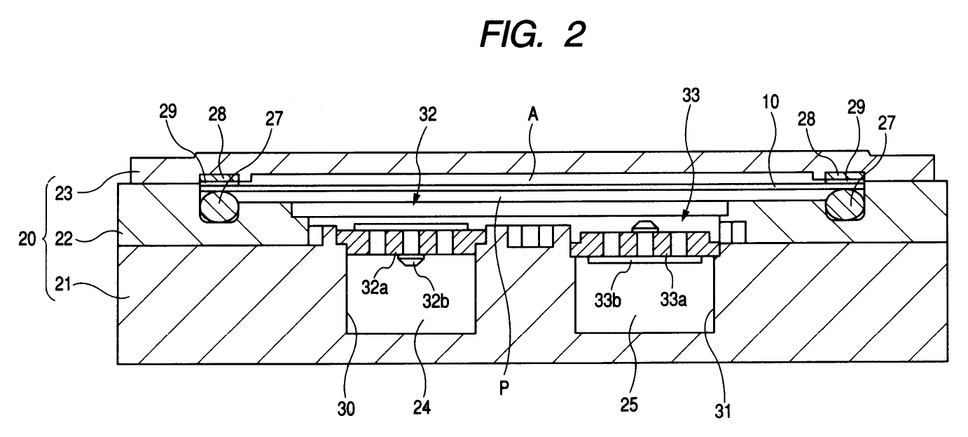

FIGS. 1 and 2 depict basic structure of a piezoelectric pump according to an embodiment of the present disclosure. A piezoelectric pump 20 may include a lower housing 21, a middle housing 22, and an upper housing 23 laminated from the bottom of FIGS. 1 and 2 in this order.

The lower housing 21 may be provided with an inlet port 24 and a discharge port 25 for a coolant (liquid). A piezoelectric vibrator 10 and a ring-shaped electrode terminal 29 may be fluid-tightly supported by a pair of ring-shaped support members (an 0-ring 27 and a guide 28) between the middle housing 22 and the upper housing 23, and a pump chamber P may be formed between the piezoelectric vibrator 10 and the middle housing 22. An air chamber A may be formed between the piezoelectric vibrator 10 and the upper housing 23. The air chamber A may be opened or airtightly sealed.

An intake passage 30 through which the inlet port 24 and the pump chamber P communicate with each other, and a discharge passage 31 through which the pump chamber P and the discharge port 25 communicate with each other may be formed in the lower housing 21 and the middle housing 22. Check valves (umbrellas) 32 and 33 may be provided in the intake passage 30 and the discharge passage 31 of the middle housing 22, respectively. The check valve 32 may be a suction check value that allows the flow of liquid from the inlet port 24 to the pump chamber P, but may prevent the flow of liquid in the opposite direction thereof. The check valve 33 may be a discharge check value that allows the flow of liquid from the pump chamber P to the discharge port 25, but prevents the flow of liquid in the opposite direction thereof. The check valves 32 and 33 according to the embodiment shown in FIGS. 1 and 2 may have the same structure, and may include substrates 32a and 33a having openings formed therein that may be adhered to or fixed to the passages by fusing, and umbrellas 32b and 33b that may be formed of an elastic material and mounted to the substrates 32a and 33a, respectively.

A rectangular concave portion 21a may be formed in the lower housing 21 at a position isolated from the intake passage 30 and the discharge passage 31, and a driver circuit board 26 for controlling the driving of the piezoelectric vibrator 10 may be fluid-tightly provided between the concave portion 21a and the middle housing 22.

In the piezoelectric pump 20, when the piezoelectric vibrator 10 is elastically deformed (vibrated) forward and backward, the suction check valve 32 may be opened, and the discharge check value 33 may be closed during a process of increasing the volume of the pump chamber P during a process of increasing the volume of the pump chamber P. As a result, a liquid may flow from the inlet port 24 to the pump chamber P. Meanwhile, during a process of decreasing the volume of the pump chamber P, the discharge check valve 33 may be opened, and the suction check valve 32 may be closed. As a result, a liquid may flow from the pump chamber P to the discharge port 25. Therefore, a pumping operation by elastically deforming (vibrating) the piezoelectric vibrator 10 forward and backward continuously may be performed.

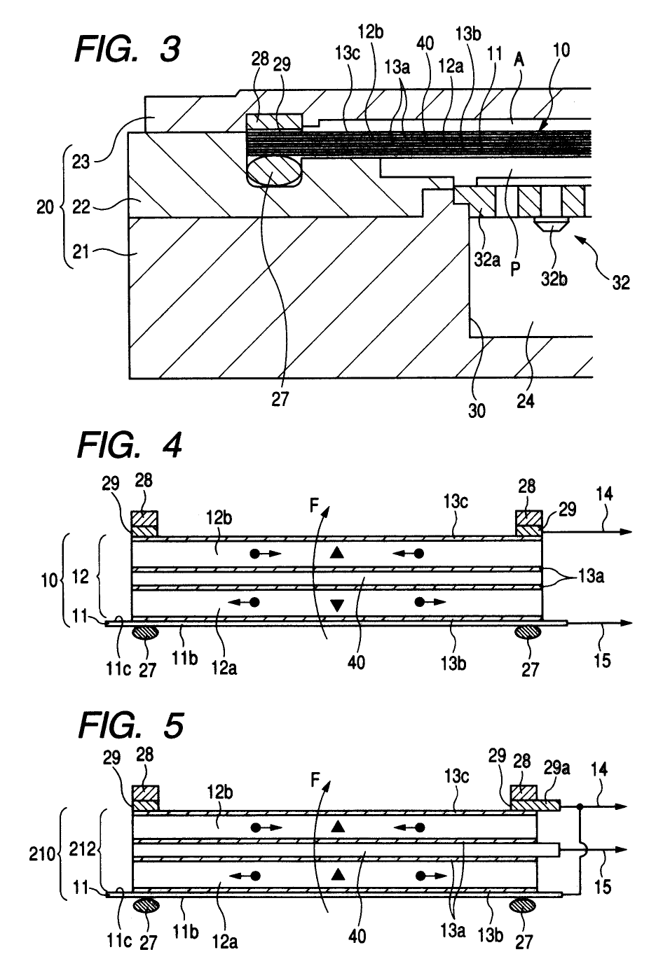

The present disclosure may be characterized in the structure of the piezoelectric vibrator 10 of the piezoelectric pump 20 having the above-mentioned structure. Next, the piezoelectric vibrator 10 according to the embodiment of the present disclosure will be described with reference to FIGS. 3 to 7.

The piezoelectric vibrator 10 may include a circular main shim 11 and a circular laminated piezoelectric element 12 formed on one of the front and rear surfaces of the main shim 11.

The main shim 11 may be a conductive thin metal plate with a thickness of about 30 to about 300 μthat may be formed of, for example, stainless steel or 42 alloy, and has sufficient rigidity to support the laminated piezoelectric element 12. The main shim 11 may have a wiring protrusion 11a for electrical connection formed in a circumferential portion thereof, a rear surface (one surface) lib abutting on the pump chamber P, and a front surface (the other surface) 11c on which the laminated piezoelectric element 12 is formed. A concave portion 22a corresponding to the wiring protrusion 11a may be formed in the middle housing 22 so as to face the pump chamber P.

The laminated piezoelectric element 12 may have a two-layer structure of a lower piezoelectric element layer 12a and an upper piezoelectric element layer 12b formed on the front surface 11c of the main shim 11 in this order, and may face the air chamber A. An intermediate electrode layer 13a may be interposed between the lower piezoelectric element layer 12a and the upper piezoelectric element layer 12b. The intermediate electrode layer 13a may electrically insulate the lower piezoelectric element layer 12a from the upper piezoelectric element layer 12b. The lower piezoelectric element layer 12a and the upper piezoelectric element layer 12b may have the same shape and thickness, and the diameter of each of the lower piezoelectric element layer 12a and the upper piezoelectric element layer 12b may be equal to or slightly smaller than that of a circular portion of the main shim 11.

The lower piezoelectric element layer 12a and the upper piezoelectric element layer 12b may be polarized and connected to wiring lines such that the amplitude of the vibration of the piezoelectric vibrator 10 is larger than that in the structure in which a piezoelectric element of the piezoelectric vibrator 10 includes a single layer. In this way, the displacement of a piezoelectric vibrator may be ensured. The lower piezoelectric element layer 12a and the upper piezoelectric element layer 12b may be polarized in opposite directions, as represented by triangles depicted in FIG. 4. When positive and negative voltages are applied, the piezoelectric element (layer) may be elastically deformed in the direction in which the surface area thereof increases or decreases. The lower piezoelectric element layer 12a close to the main shim 11 may be electrically connected to a second feeder line 15 through a shim-side electrode layer 13b and the main shim 11, and the upper piezoelectric element layer 12b close to the air chamber A may be electrically connected to a first feeder line 14 through a surface electrode layer 13c and the ring-shaped electrode terminal 29. In other words, the lower piezoelectric element layer 12a and the upper piezoelectric element layer 12b may be electrically connected in series to each other (series connection).

In the laminated piezoelectric element 12, the surface electrode layer 13c exposed to the air chamber A may be formed of Au. Meanwhile, intermediate electrode layers 13a and the shim-side electrode layer 13b may be formed of Au, Ag, or an Ag-based conductive material including Ag. Since a conductive material having migration resistance, Au may prevent the migration of the surface electrode layer 13c due to driving for a long time. Meanwhile, since the intermediate electrode layers 13a and the shim-side electrode layer 13b that are not exposed to the air chamber A do not need migration resistance as much as the surface electrode layer 13c, they may be formed of Ag or an Ag-based conductive material having good adhesion to the main shim 11. Therefore, the electrodes may be prevented from peeling off due to driving for a long time, and manufacturing costs may be reduced, as compared to the structure in which the intermediate electrode layers 13a and the shim-side electrode layer 13b are formed of Au. This combination of electrodes may lengthen the life span of the piezoelectric vibrator 10.

In the piezoelectric vibrator 10, both sides of a circumferential portion of the laminated piezoelectric element 12 may be supported by a pair of ring-shaped elastic support members (the O-ring 27 and the guide 28). The O-ring 27 may be provided between the middle housing 22 and the piezoelectric vibrator 10, may come into contact with a circumferential portion of the rear surface 11b of the main shim 11, and may apply pressure upward in the drawings. Meanwhile, the guide 28 may be provided between the upper housing 23 and the piezoelectric vibrator 10, may come into contact with the ring-shaped electrode terminal 29 that is adhered to the surface electrode layer 13c of the laminated piezoelectric element 12, and may press a circumferential portion of the laminated piezoelectric element 12 in the downward direction of the drawings, with the ring-shaped electrode terminal 29 interposed therebetween. The structure supporting both sides of the laminated piezoelectric element 12 may increase the mechanical strength (support strength) of the piezoelectric vibrator 10 and the closing pressure thereof (the internal pressure of a discharge passage (system) when a suction umbrella and a discharge umbrella are closed (when no liquid flows)). In addition, since a pair of ring-shaped support members 27 and 28 come into contact with a circumferential portion of the laminated piezoelectric element 12 that is minimally deformed, the ring-shaped support members may not substantially hinder the displacement of the laminated piezoelectric element 12.

The ring-shaped electrode terminal 29 may be a ring-shaped conductive thin metal plate that may be stably connected to the surface electrode layer 13c without hindering the displacement of the upper piezoelectric element layer 12b, and may include a ring-shaped portion 29b adhered to a circumferential portion of the surface electrode layer 13c and a wiring protrusion 29a for electrical connection that extends from the ring-shaped portion 29b. The wiring protrusion 29a may be electrically connected to the first feeder line 14. The wiring protrusion 29a and the wiring protrusion 11a of the main shim 11 may form a pair, and may be accommodated in the concave portion 22a of the middle housing 22. The ring-shaped electrode terminal 29 may be formed of, for example, 42 alloy with a thickness of about 30 μ.

The piezoelectric vibrator 10 may include an intermediate shim 40 interposed between the lower piezoelectric element layer 12a and the upper piezoelectric element layer 12b, in addition to the main shim 11. The intermediate shim 40 may be a circular or ring-shaped elastic metal member (in this embodiment, a circular shape) that has mechanical recovery and is deformable with the displacement of the laminated piezoelectric element 12. The mechanical recovery of the intermediate shim 40 may be higher than that of the main shim 11, and the intermediate shim 40 may not hinder the displacement of the laminated piezoelectric element 12. The intermediate shim 40 may be formed of the same material as that forming the main shim 11 to be thicker than the main shim 11. Specifically, the intermediate shim 40 may be formed of, for example, a thin metal plate with a thickness of about 50 to about 600 μthat is made of, for example, 42 alloy. The intermediate shim 40 may improve the mechanical strength and closing pressure of the laminated piezoelectric element 12 and thus the piezoelectric vibrator 10. The intermediate shim 40 may be provided between the lower piezoelectric element layer 12a and the upper piezoelectric element layer 12b, that is, in the middle of the laminated piezoelectric element 12. Since the intermediate shim 40 is a neutral sheet for a couple of forces F generated when an alternating electric field is applied to the laminated piezoelectric element 12, the intermediate shim 40 may increase the displacement of the laminated piezoelectric element 12. The intermediate electrode layers 13a may be provided among the intermediate shim 40, the lower piezoelectric element layer 12a, and the upper piezoelectric element layer 12b. In addition, the first feeder line 14 may be connected to the surface electrode layer 13c by, for example, soldering, instead of the ring-shaped electrode terminal 29, and the ring-shaped support member 28 may directly support the surface electrode layer 13c of the laminated piezoelectric element 12.

When an alternating electric field is applied between the first feeder line 14 and the second feeder line 15, at the moment when a positive voltage is applied to the first feeder line 14 and a negative voltage is applied to the second feeder line 15, as represented by arrows depicted in FIG. 4, the surface area of the lower piezoelectric element layer 12a may increase, and the surface area of the upper piezoelectric element layer 12b may decrease. Then, the laminated piezoelectric element 12 may deform the piezoelectric vibrator 10 to protrude downward in FIG. 4 (generates a couple of forces F). In this state, when the levels of the voltages applied to the first feeder line 14 and the second feeder line 15 are reversed, the laminated piezoelectric element 12 may deform the piezoelectric vibrator 10 to protrude upward in FIG. 4. When this operation is repeated, the piezoelectric vibrator 10 may be vibrated. In this case, the amplitude of the vibration may be larger than that in the structure in which the laminated piezoelectric element 12 includes a single piezoelectric element layer. During a pumping operation, pressure may be applied to a passage due to liquid flowing through the passage. As described above, in this embodiment, the mechanical strength of the piezoelectric vibrator 10 may be maintained at a high level by the intermediate shim 40 interposed between the lower piezoelectric element layer 12a and the upper piezoelectric element layer 12b, and thus high closing pressure may be obtained. Therefore, a stable pumping operation may be performed even when pressure is applied to the passage due to the liquid flowing through the passage.

The series type laminated piezoelectric element 12 including the intermediate shim 40 according to this embodiment may be formed as follows: the lower piezoelectric element layer 12a and the upper piezoelectric element layer 12b may be individually formed; a polarizing process may be performed on the lower piezoelectric element layer 12a and the upper piezoelectric element layer 12b to polarize them in opposite directions; and the lower piezoelectric element layer 12a and the upper piezoelectric element layer 12b may be electrically connected in series to each other with the intermediate shim 40 interposed therebetween. Specifically, the lower piezoelectric element layer 12a may be formed as follows: a piezoelectric green sheet may be cut into a circular shape in plan view by dies cutting; a single-layer sheet or a laminate of a plurality of sheets may be baked; electrode layers (the shim-side electrode layer 13b and the intermediate electrode layer 13a) may be formed on the front and rear surfaces of the baked circular sheet; and a polarizing process may be performed on the circular sheet using the electrode layers formed on the front and rear surfaces thereof. The upper piezoelectric element layer 12b may be formed as follows: a piezoelectric green sheet may be cut into a circular shape in plan view by dies cutting; a single-layer sheet or a laminate of a plurality of sheets may be baked; electrode layers (the surface electrode layer 13c and the intermediate electrode layer 13a) may be formed on the front and rear surfaces of the baked circular sheet; and a polarizing process may be performed on the circular sheet using the electrode layers formed on the front and rear surfaces thereof to polarize the circular sheet in a direction opposite to the polarization direction of the lower piezoelectric element layer 12a. Then, the intermediate electrode layer 13a of the lower piezoelectric element layer 12a may be adhered to one of the front and rear surfaces of the intermediate shim 40, the intermediate electrode layer 13a of the upper piezoelectric element layer 12b may be adhered to the other surface of the intermediate shim 40, and the main shim 11 and the shim-side electrode layer 13b of the lower piezoelectric element layer 12a may be adhered to each other. In this case, for example, a conductive resin adhesive may be used to bond the layers. In this way, the laminated piezoelectric element 12 including the lower piezoelectric element layer 12a and the upper piezoelectric element layer 12b that are polarized in opposite directions and electrically connected in series to each other, and the intermediate shim 40 interposed between the two piezoelectric element layers may be obtained. According to this forming method, a side electrode or a through hole electrode for the polarizing process may not be needed. Therefore, the series type laminated piezoelectric element 12 may be easily formed. The overall thickness of the laminated piezoelectric element 12 may be in a range of about 50 to about 1000 μm.

FIG. 5 depicts a piezoelectric vibrator 210 according to an embodiment of the present disclosure. In this embodiment, which is a variation of the embodiment of FIGS. 1 to 3, instead of the series type laminated piezoelectric element 12, a parallel type laminated piezoelectric element 212 may be provided. This embodiment may be similar to the embodiment of FIGS. 1 to 4 except for the structure of the laminated piezoelectric element 212. In FIG. 5, for example, the same components as those in the embodiment shown in FIGS. 1 to 4 are denoted by the same reference numerals.

The laminated piezoelectric element 212 may have a two-layer structure of the lower piezoelectric element layer 12a and the upper piezoelectric element layer 12b formed on the front surface 11c of the main shim 11 in this order, and may face the air chamber A. A pair of intermediate electrode layers 13a and the intermediate shim 40 may be interposed between the lower piezoelectric element layer 12a and the upper piezoelectric element layer 12b. As described above, the intermediate shim 40 may be a circular or ring-shaped elastic metal member (in this embodiment, a circular shape) that has mechanical recovery and is deformable with the displacement of a laminated piezoelectric element 212. The intermediate shim 40 may improve the mechanical strength and closing pressure of the laminated piezoelectric element 212 and thus the piezoelectric vibrator 210. The intermediate shim 40 may be provided between the lower piezoelectric element layer 12a and the upper piezoelectric element layer 12b, that is, in the middle of the laminated piezoelectric element 212. Since the intermediate shim 40 is a neutral sheet for a couple of forces F generated when an alternating electric field is applied to the laminated piezoelectric element 212, the intermediate shim 40 may increase the displacement of the laminated piezoelectric element 212. The intermediate shim 40 may also serve as an electrode terminal for electrically connecting the intermediate electrode layers 13a and the second feeder line 15. Therefore, a side electrode or a through hole electrode for electrically connecting the intermediate electrode layers 13a may not be needed, which makes connecting wiring lines easier to perform. The shim-side electrode layer 13b and the surface electrode layer 13c may be electrically connected to the first feeder line 14 through the main shim 11 and the ring-shaped electrode terminal 29. In other words, the lower piezoelectric element layer 12a and the upper piezoelectric element layer 12b may be electrically connected in parallel to each other (parallel connection). In this embodiment, the first feeder line 14 may be connected to the surface electrode layer 13c by, for example, soldering, instead of the ring-shaped electrode terminal 29, and the ring-shaped support member 28 may directly support the surface electrode layer 13c of the laminated piezoelectric element 212.

In the embodiment of FIG. 5, the lower piezoelectric element layer 12a and the upper piezoelectric element layer 12b may be polarized in the same direction. Therefore, when an alternating electric field is applied between the first feeder line 14 and the second feeder line 15, the surface area of one of the lower piezoelectric element layer 12a and the upper piezoelectric element layer 12b may increase, but the surface area of the other piezoelectric element layer may decrease. The amplitude of the vibration of the piezoelectric vibrator 210 may be larger than that in the structure in which a piezoelectric element of the piezoelectric vibrator 210 includes only a single piezoelectric element layer. Since the mechanical strength of the piezoelectric vibrator 210 is maintained at a high level by the intermediate shim 40 interposed between the lower piezoelectric element layer 12a and the upper piezoelectric element layer 12b, high closing pressure may be obtained, similar to the embodiment of FIGS. 1 to 4. Therefore, a stable pumping operation may be performed even when pressure is applied to a passage due to the liquid flowing through the passage.

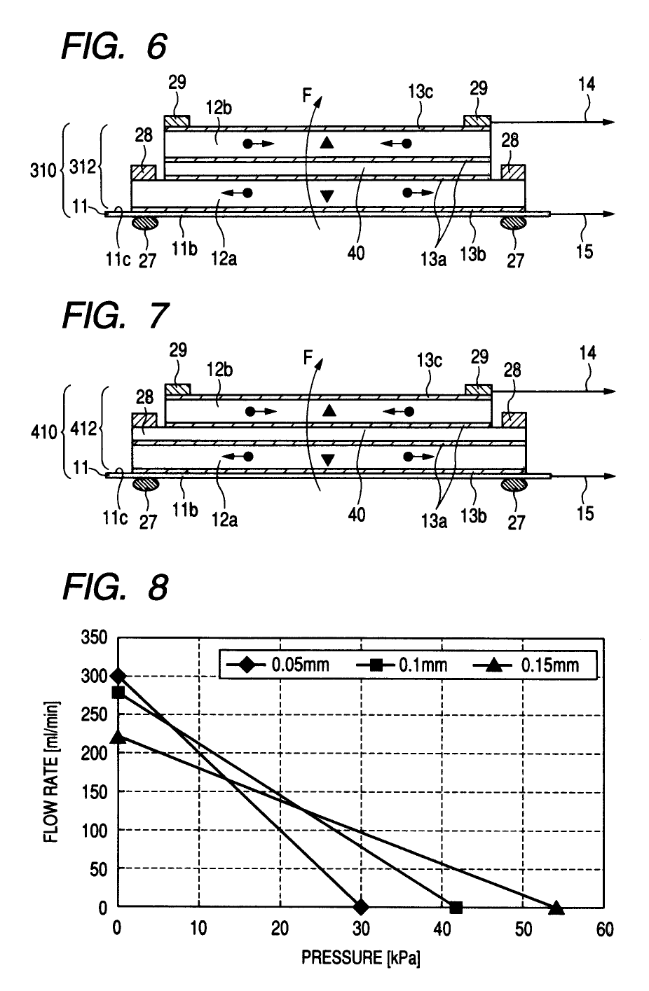

FIG. 6 depicts a piezoelectric vibrator 310 according to an embodiment of the present disclosure. In this embodiment, which is a variation of the first embodiment, an intermediate shim 40 may have a smaller diameter than the lower piezoelectric element layer 12a below the intermediate shim 40, and both sides of a circumferential portion of the lower piezoelectric element layer 12a may be supported by a pair of ring-shaped support members 27 and 28. In a laminated piezoelectric element 312, layers (intermediate electrode layers 13a, an intermediate shim 40, an upper piezoelectric element layer 12b, and a surface electrode layer 13c) on the lower piezoelectric element layer 12a may have a smaller diameter than the lower piezoelectric element layer 12a and a layer below the lower piezoelectric element layer 12a (a shim-side electrode layer 13b). Therefore, the overall shape of the laminated piezoelectric element 312 may be a convex shape in a cross-sectional view. A circumferential portion of the lower piezoelectric element layer 12a may be exposed from the intermediate shim 40 and the upper piezoelectric element layer 12b, and the exposed portion may come into direct contact with the guide 28. The guide 28 may be formed in a ring shape having a diameter equal to that of the lower piezoelectric element layer 12a, but may not contact the upper piezoelectric element layer 12b. In other words, the upper piezoelectric element layer 12b may be deformable without being restricted by the guide 28. However, the diameter of the intermediate electrode layers 13a formed on the lower piezoelectric element layer 12a may be equal to that of the lower piezoelectric element layer 12a. According to this embodiment, since both sides of a circumferential portion of the lower piezoelectric element layer 12a are supported by the support members, the mechanical strength and closing pressure of the piezoelectric vibrator 310 may be improved, and the upper piezoelectric element layer 12b may be freely deformed. As a result, displacement of the piezoelectric vibrator 310 may be increased. In addition, since the guide 28 is provided in a step portion between the lower piezoelectric element layer 12a and the upper piezoelectric element layer 12b, the thickness of a housing may be reduced. In this embodiment, the series type laminated piezoelectric element 312 may be used, but a parallel type laminated piezoelectric element may also be used. In this embodiment, the first feeder line 14 may be connected to the surface electrode layer 13c by, for example, soldering, instead of the ring-shaped electrode terminal 29.

FIG. 7 depicts a piezoelectric vibrator 410 according to an embodiment of the present disclosure. In this embodiment, which is a modification of the third embodiment, an intermediate shim 40 may extend to a circumferential portion of the lower piezoelectric element layer 12a, and the guide 28 may press the circumferential portion of the lower piezoelectric element layer 12a in the upward direction of FIG. 7, with the intermediate shim 40 interposed therebetween. That is, the O-ring 27 and the guide 28 may support both sides of the circumference of a laminate of the intermediate shim 40, the main shim 11, and the lower piezoelectric element layer 12a interposed between the two shims. As such, when the intermediate shim 40 is interposed between a pair of ring-shaped support members 27 and 28, the strength of the supported portion may be improved, and thus the mechanical strength and closing pressure of the piezoelectric vibrator 410 may also be improved.

In the laminated piezoelectric element 412 according to the embodiment of FIG. 7, the intermediate shim 40 and layers (an intermediate electrode layers 13a on the lower piezoelectric element layer 12a, the lower piezoelectric element layer 12a, and a shim-side electrode layer 13b) below the intermediate shim 40 may have a larger diameter than layers (an intermediate electrode layers 13a underneath the upper piezoelectric element layer 12b, the upper piezoelectric element layer 12b, and a surface electrode layer 13c) on the intermediate shim 40. Therefore, the overall shape of the laminated piezoelectric element 412 may be a convex shape in a cross-sectional view. The guide 28 may be formed in a ring shape having a diameter equal to that of the lower piezoelectric element layer 12a, but may not contact the upper piezoelectric element layer 12b. Therefore, the upper piezoelectric element layer 12b may be deformable without being restricted by a pair of ring-shaped support members 27 and 28.

According to the embodiment of FIG. 7, since the support members support both sides of a circumferential portion of a laminate of the intermediate shim 40, the main shim 11, and the lower piezoelectric element layer 12a interposed between the two shims, the mechanical strength and closing pressure of the piezoelectric vibrator 410 may be improved, and the upper piezoelectric element layer 12b may be freely deformed. As a result, the displacement of the piezoelectric vibrator 410 may be increased. In addition, since the guide 28 is provided in a step portion between the lower piezoelectric element layer 12a and the upper piezoelectric element layer 12b, the thickness of a housing may be reduced. In this embodiment, the series type laminated piezoelectric element 412 may be used, but a parallel type laminated piezoelectric element may also be used. In this embodiment, the first feeder line 14 may be connected to the surface electrode layer 13c by, for example, soldering, instead of the ring-shaped electrode terminal 29.

FIG. 8 depicts a graph illustrating the flow rate [ml/min] and the pressure [kpa] of liquid measured at a predetermined position in a flow passage while changing the thickness of the intermediate shim 40 in the piezoelectric pump 20 using the piezoelectric vibrator 310 according to the third embodiment. The measurement may be made under the conditions that the piezoelectric vibrator 310 is operated at a driving voltage of 120 V and a driving frequency of 60 Hz. In the piezoelectric vibrator 310, the main shim 11 may have a thickness of 0.03 mm, and the lower piezoelectric element layer 12a and the upper piezoelectric element layer 12b may each have a thickness of 0.2 mm. In the graph shown in FIG. 8, diamonds depict measured values when the intermediate shim 40 has a thickness of 0.05 mm, rectangles depict measured values when the intermediate shim 40 has a thickness of 0.1 mm, and triangles depict measured values when the intermediate shim 40 has a thickness of 0.15 mm.

As depicted in FIG. 8, as the thickness of the intermediate shim 40 becomes larger than that of the main shim 11, the closing pressure (pressure when no liquid flows) may tend to increase. Therefore, when the resistance of a flow passage is large, the thickness of the intermediate shim 40 may be larger than that of the main shim 11.

According to the above-described embodiments, since the intermediate shim 40 having mechanical recovery is interposed between a plurality of piezoelectric element layers of the piezoelectric vibrator 10 (210, 310, and 410), the mechanical strength and closing pressure of the piezoelectric vibrator 10 (210, 310, and 410) may be improved while increasing the displacement of the piezoelectric vibrator 10 (210, 310, and 410). Therefore, a stable pumping operation may be performed without the deformation of the piezoelectric vibrator 10 (210, 310, and 410) due to the internal pressure of a flow passage system. In this way, coping with a reduction in the thickness of the main shim 11 may be more easily handled.

In the above-described embodiments, in the piezoelectric vibrators 10, 210, 310, and 410, a plurality of piezoelectric element layers may be formed on one of the front and rear surfaces of the main shim 11, but the present disclosure is not limited thereto. The present disclosure may be applied to a piezoelectric vibrator having a plurality of piezoelectric element layers formed on both the front and rear surfaces of the main shim 11. In the piezoelectric vibrator having a plurality of piezoelectric element layers formed on both the front and rear surfaces of the main shim 11, the intermediate shims 40 may be interposed between the plurality of piezoelectric element layers formed on the front and rear surfaces of the main shim 11. In addition, the piezoelectric element of the piezoelectric vibrator may include a single layer or three or more layers.

1. A piezoelectric pump comprising:
a piezoelectric vibrator whose periphery is fluid-tightly sealed; and
a pump chamber and an air chamber that are formed on front and rear sides of the piezoelectric vibrator, wherein the piezoelectric vibrator comprises:
a main shim that is formed of a conductive thin metal plate;
a plurality of piezoelectric element layers that are formed on the main shim; and
an intermediate shim that is formed between the plurality of piezoelectric element layers and is made of an elastic metal material having mechanical recovery; and
wherein the piezoelectric vibrator is vibrated to perform a pumping operation.

2. The piezoelectric pump of claim 1, wherein the intermediate shim is provided in the middle of the plurality of piezoelectric element layers.

3. The piezoelectric pump of claim 1, wherein, in the piezoelectric vibrator, one surface of the main shim abuts on the pumping chamber, and the plurality of piezoelectric element layers and the intermediate shim are formed on the other surface of the main shim.

4. The piezoelectric pump of claim 1, wherein the intermediate shim has higher mechanical recovery than the main shim.

5. The piezoelectric pump of claim 1, wherein the intermediate shim and the main shim are formed of the same material, and the thickness of the intermediate shim is larger than that of the main shim.

6. The piezoelectric pump of claim 1, wherein the plurality of piezoelectric element layers are polarized and connected to wiring lines such that the amplitude of the vibration of the piezoelectric vibrator is larger than that of a piezoelectric vibrator including a single-layer piezoelectric element.

7. The piezoelectric pump of claim 3, wherein the intermediate shim of the piezoelectric vibrator has a smaller diameter than a piezoelectric element layer below the intermediate shim, and a pair of ring-shaped support members support both sides of a circumferential portion of the piezoelectric element layer below the intermediate shim.

8. The piezoelectric pump of claim 3, wherein the intermediate shim of the piezoelectric vibrator has a larger diameter than a piezoelectric element layer above the intermediate shim, and a pair of ring-shaped support members support both sides of a circumferential portion of a laminate of the intermediate shim, the main shim, and a piezoelectric element layer between the two shims.

9. A piezoelectric vibrator comprising:
a main shim that is formed of an elastic metal material having mechanical recovery;
a plurality of piezoelectric element layers that are formed on the main shim; and
an intermediate shim that is formed of an elastic metal material having mechanical recovery and is provided between the plurality of piezoelectric element layers.

10. The piezoelectric vibrator of claim 9, wherein the intermediate shim has higher mechanical recovery than the main shim.

11. The piezoelectric vibrator of claim 9, wherein the intermediate shim and the main shim are formed of the same material, and the thickness of the intermediate shim is larger than that of the main shim.
